(19) United States
(12) Patent Application Publication
(10) Pub. No.: US 2015/0096495 A1
(43) Pub. Date: Apr. 9, 2015

(54) APPARATUS AND METHOD OF ATOMIC LAYER DEPOSITION

(71) Applicant: MTS Nanotech Inc., Suwon-si (KR)

(72) Inventor: In Kwon Jeong, Cupertino, CA (US)

(73) Assignee: MTS Nanotech Inc., Suwon-si (KR)

(21) Appl. No.: 14/570,217

(22) Filed: Dec. 15, 2014

Related U.S. Application Data
(63) Continuation of application No. PCT/KR2013/005416, filed on Jun. 19, 2013.

(30) Foreign Application Priority Data
Jun. 20, 2012 (KR) 10-2012-0065954
Aug. 6, 2012 (KR) 10-2012-0085499
Nov. 26, 2012 (KR) 10-2012-0134150

(51) Int. Cl. C23C 16/458; C23C 16/455; C23C 16/52

(52) U.S. Cl. CPC C23C 16/458; C23C 16/52; C23C 16/45565
USPC 118/729

(57) ABSTRACT

An apparatus for depositing atomic layers comprises a substrate moving mechanism, a showerhead comprising at least one injection unit, and a showerhead reciprocating mechanism. The showerhead injects source and reactant precursors to the substrate while the substrate is transported. The number of the atomic layers deposited on the substrate can be controlled by controlling the moving speed of the substrate and the reciprocating speed of the showerhead. The invention provides an apparatus and a method with high throughput and small footprint. The invention also provides an apparatus and a method configured to deposit the atomic layers on a gas permeable substrate.

### CROSS REFERENCE TO RELATED APPLICATION

This application is a continuation of PCT Patent Application No. PCT/KR2013/005416 filed on Jun. 19, 2013, which claims the benefit of KR Patent Application Ser. Nos. 10-2012-0065954 filed on Jun. 20, 2012, 10-2012-0085499 filed on Aug. 6, 2012, and 10-2012-0134150 filed on Nov. 26, 2012, which are all incorporated herein by reference.

### FIELD OF THE INVENTION

The invention relates generally to a thin film deposition apparatus, and more particularly to an apparatus and a method for depositing atomic layers on substrates.

### BACKGROUND OF THE INVENTION

Atomic layer deposition is widely used to deposit thin films on semiconductor wafers and its application is extended to deposit thin films on CIGS solar cells, Si solar cells and OLED displays. Typical atomic layer deposition process consists of the following four steps.

At the first step, source precursor such as TMA (trimethyl-aluminum) is injected to the substrate. The source precursor reacts with the surface of the substrate and coats the surface with a first reaction layer.

At the second step, which is a purge step, the source precursor adsorbed physically on the surface of the substrate is removed by injecting inert gas such as nitrogen to the substrate.

At the third step, reactant precursor such as H₂O is injected to the substrate. The reactant precursor reacts with the first reaction layer and coats the substrate with a second reaction layer.

At the fourth step, which is the purge step, the reactant precursor adsorbed physically on the surface of the substrate is removed by injecting the inert gas. Through the cycle, a single layer of thin film consisting of the first and second reaction layers, for example Al₂O₃ thin film, is deposited on the substrate. To get a thin film with a desired thickness the cycle is repeated.

Deposition speed of the thin film by the atomic layer deposition process is determined by the time required to complete the cycle of the four steps. Therefore the atomic layer deposition has a disadvantage that the deposition speed is slow because the supplies of the source precursor, the purge gas, the reactant precursor and the purge gas must be sequential.

Referring to FIG. 1, another ALD (atomic layer deposition) method, so called space-divided ALD, is described. FIG. 1 is a side view of an ALD apparatus according to the space-divided ALD. In the space-divided ALD, the source and reactant precursors are sequentially coated on the substrate 50 by moving the substrate 50 through under a showerhead 20, which has a hole 21 for injecting the purge gas, a hole 22 for exhaust, a hole 23 for injecting the source precursor, a hole 24 for exhaust, a hole 25 for injecting the purge gas, a hole 26 for exhaust, and a hole 27 for injecting the reactant precursor. The holes for injecting the gases 21, 23, 25 and 27 and the holes for exhaust 22, 24 and 26 are disposed sequentially along a first direction, which is the moving direction of the substrate 50, as illustrated in FIG. 1.

The source precursor injected from the hole 23 is exhausted through its neighboring holes for exhaust 22 and 24. The reactant precursor injected from the hole 27 is exhausted through the hole for exhaust 26. The purge gas injected from the hole 25 is exhausted through its neighboring holes for exhaust 24 and 26.

If the substrate 50 is flexible, the substrate 50 can be rolled as illustrated in FIGS. 2 and 3. FIGS. 2 and 3 are side and top views of the ALD apparatus, respectively, for depositing the atomic layers on the flexible substrate 50. A roll 50a of the substrate, on which the atomic layers will be deposited, is disposed at an opposite side of a roll 50b of the substrate, on which the atomic layers have been deposited, across the showerhead 20. The source and reactant precursors can be sequentially coated on the substrate 50 by moving the substrate 50 through under the showerhead 20 along the first direction, which is perpendicular to a width direction 50w of the substrate 50. In this type of the roll-to-roll system, similarly, the holes for injecting the gases 21, 23, 25 and 27 and the holes for exhaust 22, 24 and 26 are disposed sequentially along the first direction, which is the moving direction of the substrate 50, and the holes for injecting the gases and the holes for exhaust are extended along a direction parallel to the width direction 50w of the substrate 50 as illustrated in FIG. 3. Because the roll-to-roll system must have as many sets of the showerhead 20 along the first direction as the number of the atomic layers to deposit, the system has a disadvantage that the footprint is increased. For example, the system needs 100 sets of the showerhead 20 in order to deposit 100 atomic layers.

If the system does not have enough sets of the showerhead 20, the substrate 50 must repeat being wound back and forth, which increases possibility of generating particles and scratches.

In addition, the moving speed of the substrate 50, which is the speed that the roll 50b winds the substrate 50, must be as high as possible in order to improve the throughput.

In addition, the particles can be generated if the source and reactant precursors meet during the high speed moving of the substrate and make a gas phase reaction because the conventional space-divided ALD is configured to inject the source and reactant precursors simultaneously to the substrate.

In case that the substrate 50 is permeable to gas, it is difficult to exhaust the source and reactant precursors and the purge gas injected from the showerhead 20 through the holes for exhaust 22, 24, 26 and 28 of the showerhead 20 because they are permeated through the substrate 50 to an opposite side of the showerhead 20. In other words, it is difficult to exhaust the source and reactant precursors through the holes for exhaust 22, 24, 26 and 28 of the showerhead 20 with the source and reactant precursors spatially separated by the purge gas such that they are not mixed.

As described above, ALD requires an apparatus and a method that are designed to deposit a desired number of the atomic layers with a small footprint of the apparatus. ALD also requires an apparatus and a method that are designed to deposit the desired number of the atomic layers with a single winding process of the substrate without repeating the back and forth winding processes of the substrate. ALD also requires an apparatus and a method that are designed to deposit the atomic layers at a high speed without increasing the moving speed of the substrate. ALD also requires an apparatus and a method that are designed to prevent the gas phase reaction which is made when the source and reactant precursors meet. ALD also requires an apparatus and a method that are designed to exhaust efficiently the source and reactant precursors and the purge gas, which are injected from the showerhead, in case that the substrate is permeable to gas.

### SUMMARY OF THE INVENTION

A goal of an embodiment of the invention is to provide an atomic layer deposition apparatus and a method to deposit a desired number of the atomic layers with a small footprint of the apparatus.

A goal of an embodiment of the invention is to provide an atomic layer deposition apparatus and a method to deposit the atomic layers at a high speed with a low moving speed of the substrate.

A goal of an embodiment of the invention is to provide an atomic layer deposition apparatus and a method to deposit a desired number of the atomic layers with a single winding process of the substrate without repeating the back and forth winding processes of the substrate.

A goal of an embodiment of the invention is to provide an atomic layer deposition apparatus and a method designed to prevent a problem that the source and reactant precursors are mixed.

A goal of an embodiment of the invention is to provide an atomic layer deposition apparatus and a method to exhaust efficiently the source and reactant precursors and the purge gas in case that the substrate is permeable to gas.

An apparatus for depositing the atomic layers according to an embodiment of the invention injects the source and reactant precursors from a showerhead while the showerhead reciprocates. However, the showerhead does not inject the reactant precursor while the source precursor is injected from the showerhead, and the showerhead does not inject the source precursor while the reactant precursor is injected from the showerhead. For example, the showerhead injects the source precursor while the showerhead moves from a first location to a second location, and the showerhead injects the reactant precursor while the showerhead moves from the second location to the first location. Therefore the problem that the source and reactant precursors are mixed can be prevented.

An apparatus for depositing the atomic layers according to an embodiment of the invention is configured such that a distance between the first and second locations is as short as a pitch of at least one injection units of the showerhead.

An apparatus for depositing the atomic layers according to an embodiment of the invention is configured such that purge gas is injected from the showerhead while the source or reactant precursor is injected to the substrate, and the injected purge gas and the source and reactant precursors are exhausted through the showerhead immediately after they are injected.

An apparatus for depositing the atomic layers according to an embodiment of the invention is configured such that the purge gas is injected from the showerhead while the source or reactant precursor is injected to the substrate and the injected purge gas and the source and reactant precursors are exhausted through a plate for exhaust, which is disposed at an opposite side of the showerhead across the substrate, immediately after they are injected. Therefore the apparatus provides a means to deposit the atomic layers on a gas permeable substrate.

An apparatus for depositing the atomic layers according to an embodiment of the invention comprises a moving mechanism configured to move a substrate along a first direction, a showerhead comprising at least one injection unit wherein the injection unit comprises a hole for injecting first materials, which extends along a second direction, a hole for injecting second materials, which extends along the second direction, wherein the second materials forms a reaction layer by a reaction with the first materials, a hole for injecting purge gas towards the substrate, which extends along the second direction; and a hole for exhaust, which extends along the second direction, and a moving mechanism configured to move the showerhead back and forth along the first direction between first and second locations.

According to an embodiment of the invention the first and second directions are perpendicular to each other and the second direction is a width direction of the substrate.

According to an embodiment of the invention a distance between the first and second locations is a pitch of the at least one injection units.

According to an embodiment of the invention the distance between the first and second locations is greater than a distance between the holes for injecting the first and second materials.

According to an embodiment of the invention the number of the atomic layers deposited on the substrate is controlled by controlling a moving speed of the substrate along the first direction.

According to an embodiment of the invention the number of the atomic layers deposited on the substrate is controlled by controlling a reciprocating speed of the showerhead along the first direction.

According to an embodiment of the invention the apparatus further comprises a second showerhead disposed before the showerhead wherein the second showerhead comprises a hole for injecting the first materials, which extends along the second direction.

According to an embodiment of the invention the apparatus further comprises a second showerhead disposed after the showerhead wherein the second showerhead comprises a hole for injecting the first materials, which extends along the second direction.

According to an embodiment of the invention the apparatus comprises a roller configured to support the substrate, wherein the showerhead is disposed adjacent to the roller and an injection surface of the showerhead is curved along a circumferential direction of the roller.

According to an embodiment of the invention the second direction is parallel to a rotational axis of the roller and the showerhead pivots back and forth along the circumferential direction of the roller.

According to an embodiment of the invention the first and second materials and the purge gas are injected and exhausted simultaneously while the showerhead moves along the first direction.

According to an embodiment of the invention the second materials is not injected while the first materials is injected, and the first materials is not injected while the second materials is injected, while the showerhead reciprocates along the first direction.

According to an embodiment of the invention only the purge gas is injected and exhausted while the showerhead moves from the first location to the second location but the first and second materials and the purge gas are injected and exhausted, while the showerhead moves from the second location to the first location.

An apparatus for depositing the atomic layers according to an embodiment of the invention comprises a moving mechanism configured to move a substrate along a first direction, a showerhead comprising at least one injection unit wherein the injection unit comprises a hole for injecting first materials, which extends along the first direction, a hole for injecting second materials, which extends along the first direction, wherein the second materials forms a reaction layer by a reaction with the first materials, a hole for injecting purge gas towards the substrate, which extends along the first direction; and a hole for exhaust which extends along the first direction, and a moving mechanism configured to move the showerhead back and forth along a second direction between first and second locations,

According to an embodiment of the invention the first and second directions are perpendicular to each other.

According to an embodiment of the invention the second direction is a width direction of the substrate.

According to an embodiment of the invention a distance between the first and second locations is a pitch of at least one injection units.

According to an embodiment of the invention the distance between the first and second locations is greater than a distance between the holes for injecting the first and second materials.

According to an embodiment of the invention the number of the atomic layers deposited on the substrate is controlled by controlling a moving speed of the substrate along the first direction.

According to an embodiment of the invention the number of the atomic layers deposited on the substrate is controlled by controlling a reciprocating speed of the showerhead along the second direction.

According to an embodiment of the invention the apparatus further comprises a second showerhead disposed before the showerhead, wherein the second showerhead comprises a hole for injecting the first materials, which extends along the second direction.

According to an embodiment of the invention the apparatus further comprises a second showerhead disposed after the showerhead, wherein the second showerhead comprises a hole for injecting the first materials, which extends along the second direction.

According to an embodiment of the invention the apparatus comprises a roller configured to support the substrate, wherein the showerhead is disposed adjacent to the roller and an injection surface of the showerhead is curved along a circumferential direction of the roller.

According to an embodiment of the invention the second direction is a circumferential direction of the roller and the showerhead moves back and forth along a direction parallel to a rotational axis of the roller.

According to an embodiment of the invention the first and second materials and the purge gas are injected and exhausted simultaneously while the showerhead moves back and forth along the second direction.

According to an embodiment of the invention the second materials is not injected while the first materials is injected, and the first materials is not injected while the second materials is injected, while the showerhead moves back and forth along the second direction.

According to an embodiment of the invention only the purge gas is injected and exhausted while the showerhead moves from the first location to the second location but the first and second materials and the purge gas are injected and exhausted, while the showerhead moves from the second location to the first location.

An apparatus for depositing the atomic layers according to an embodiment of the invention comprises a moving mechanism configured to move a substrate along a first direction, and a showerhead comprising a first injection unit wherein the first injection unit comprises a hole for injecting first materials, which extends along the second direction, a hole for injecting second materials, which extends along the second direction, wherein the second materials forms a reaction layer by a reaction with the first materials, a hole for injecting purge gas towards the substrate, which extends along the second direction; and a hole for exhaust which extends along the second direction, wherein the substrate is exposed to the first material, the purge gas, the second materials and the purge gas sequentially and repeatedly while the substrate passes between the hole for injecting the second materials and the hole for exhaust.

According to an embodiment of the invention the first and second directions are perpendicular to each other.

According to an embodiment of the invention the second direction is a width direction of the substrate.

According to an embodiment of the invention the number of the atomic layers deposited on the substrate is controlled by controlling a moving speed of the substrate along the first direction.

According to an embodiment of the invention the number of the atomic layers deposited on the substrate is controlled by controlling injection times and cycles of the first materials, the purge gas, the second materials and the purge gas.

According to an embodiment of the invention the showerhead further comprises a second injection unit, wherein the second injection unit comprises a hole for injecting the first materials, which extends along the second direction, a hole for injecting the second materials, which extends along the second direction, a hole for injecting the purge gas, which extends along the second direction, and a hole for exhaust configured to exhaust the first and second materials and the purge gas, which extends along the second direction.

According to an embodiment of the invention the hole for exhaust of the second injection unit is disposed adjacent to the hole for exhaust of the first injection unit, and the holes for injecting the first and second materials and the purge gas of the second injection unit is disposed at an opposite side of the first injection unit across the hole for exhaust of the second injection unit.

According to an embodiment of the invention the hole for exhaust of the second injection unit is the hole for exhaust of the first injection unit.

According to an embodiment of the invention the substrate is exposed to the first materials, the purge gas, the second materials and the purge gas sequentially and repeatedly while the substrate moves between the hole for exhaust and the hole for injecting the second materials of the second injection unit.

According to an embodiment of the invention the apparatus comprises a roller configured to support the substrate, wherein the showerhead is disposed adjacent to the roller and an injection surface of the showerhead is curved along a circumferential direction of the roller.

An apparatus for depositing the atomic layers according to an embodiment of the invention comprises a showerhead having first and second injection units, each of which comprises a hole for injecting first materials towards the substrate, a hole for injecting second materials towards the substrate wherein the second materials forms a reaction layer by a reaction with the first materials, a hole for injecting purge gas towards the substrate, and a hole for exhaust configured to exhaust the first and second materials and the purge gas, wherein the holes for injecting the first and second materials and the purge gas of the second injection unit is disposed at an opposite side of the first injection unit across the hole for exhaust of the second injection unit.

According to an embodiment of the invention the hole for exhaust of the second injection unit is the hole for exhaust of the first injection unit.

According to an embodiment of the invention the apparatus is configured to inject the first materials, the purge gas, the second materials and the purge gas sequentially through the showerhead.

An apparatus for depositing the atomic layers according to an embodiment of the invention comprises a moving mechanism configured to move a substrate along a first direction, a showerhead comprising at least one injection unit comprising a hole for injecting first materials, a hole for injecting second materials which forms a reaction layer by a reaction with the first materials and a hole for injecting purge gas towards the substrate and a moving mechanism configured to move the showerhead back and forth along a second direction between first and second locations, wherein the showerhead does not inject the second materials while the first material is injected and does not inject the first materials while the second material is injected, while the showerhead moves back and forth.

According to an embodiment of the invention the injection unit of the showerhead comprises at least one hole for exhaust, and the first and second materials and the purge gas are exhausted through the at least one hole for exhaust.

According to an embodiment of the invention the apparatus comprises a plate for exhaust configured to exhaust the first and second materials and the purge gas, wherein the plate for exhaust is disposed at an opposite side of the showerhead across the substrate.

According to an embodiment of the invention the substrate is permeable to gas.

According to an embodiment of the invention the first and second directions are perpendicular to each other.

According to an embodiment of the invention the first and second directions are the same.

According to an embodiment of the invention a distance between the first and second locations is a pitch of the at least one injection units.

According to an embodiment of the invention the distance between the first and second locations is greater than a distance between the holes for injecting the first and second materials.

According to an embodiment of the invention a method to deposit the atomic layers comprises a first moving step to move a showerhead between first and second locations wherein the showerhead comprises a hole for injecting first materials, a hole for injecting purge gas, a hole for injecting second materials which reacts with the first materials to form a reaction layer and a hole for injecting purge gas, an injection step of the first materials to inject the first materials to the substrate during the first moving step, a second moving step to move the showerhead between the first and second locations, and an injection step of the second materials to inject the second materials to the substrate during the second moving step.

According to an embodiment of the invention the showerhead can inject the purge gas to the substrate at the first and second moving steps.

According to an embodiment of the invention the first and second materials and the purge gas injected at the first and second moving steps can be exhausted through a hole for exhaust disposed at the showerhead.

According to an embodiment of the invention the first and second materials and the purge gas injected at the first and second moving steps can be exhausted through a hole for exhaust disposed at an opposite side of the showerhead across the substrate.

According to an embodiment of the invention the substrate is permeable to gas.

According to an embodiment of the invention the showerhead moves from the first location to the second location at the first moving step and moves from the second location to the first location at the second moving step.

According to an embodiment of the invention the showerhead moves from the first location to the second location at the first and second moving steps.

According to an embodiment of the invention the method further comprises a third moving step to move the showerhead from the second location to the first location. The first and second materials are not injected at the third moving step.

According to an embodiment of the invention the showerhead injects the purge gas to the substrate at the third moving step.

According to an embodiment of the invention a distance between the first and second locations is a pitch of the at least one injection units.

According to an embodiment of the invention the distance between the first and second locations is greater than a distance between the holes for injecting the first and second materials.

According to an embodiment of the invention the number of the atomic layers deposited on the substrate is controlled by controlling a moving speed of the substrate along the first direction.

According to an embodiment of the invention the number of the atomic layers deposited on the substrate is controlled by controlling a reciprocating speed of the showerhead along the second direction.

According to an embodiment of the invention the substrate is supported on a circular roller. The showerhead is disposed adjacent to the roller and injects the first and second materials to the substrate while the showerhead pivots back and forth along a circumferential direction of the roller.

According to an embodiment of the invention the substrate is supported on a circular roller. The showerhead is disposed adjacent to the roller and injects the first and second materials to the substrate while the showerhead moves back and forth along a direction parallel to a rotational axis of the roller.

### Advantage of the Invention

According to an embodiment of the invention, the apparatus and the method are provided that can deposit the atomic layers at a high speed with a small footprint of the apparatus.

According to an embodiment of the invention, the apparatus and the method are provided that can deposit the atomic layers at a high speed with a low moving speed of the substrate.

According to an embodiment of the invention, the apparatus and the method are provided that meeting of the source and reactant precursors is prevented fundamentally.

According to an embodiment of the invention, the apparatus and the method are provided that can deposit a desired number of the atomic layers with a single winding process of the substrate without repeating the back and forth winding processes of the substrate.

According to an embodiment of the invention, the apparatus and the method are provided that can exhaust the source and reactant precursors and the purge gas efficiently in case that the substrate is permeable to gas.

### BRIEF DESCRIPTION OF THE DRAWINGS

FIG. 1 is a side view of an atomic layer deposition apparatus according to a conventional technology.

FIG. 2 is a side view of an atomic layer deposition apparatus according to a conventional technology.

FIG. 3 is a top view of an atomic layer deposition apparatus according to a conventional technology.

FIG. 4 is a top view of the atomic layer deposition apparatus according to an embodiment of the invention.

FIGS. 5, 6 and 7 are process flow diagrams for depositing atomic layers according to embodiments of the invention.

FIG. 8 is a top view of an atomic layer deposition apparatus according to an embodiment of an invention.

FIG. 9 is a side view of an atomic layer deposition apparatus according to an embodiment of an invention.

FIG. 10 is a top view of an atomic layer deposition apparatus according to an embodiment of an invention.

FIG. 11 is a side view of an atomic layer deposition apparatus according to an embodiment of an invention.

FIG. 12 is a top view of an atomic layer deposition apparatus according to an embodiment of an invention.

FIG. 13 is a top view of an exhaust of an atomic layer deposition apparatus according to an embodiment of an invention.

FIGS. 14 and 15 are cross sectional views of an atomic layer deposition apparatus according to an embodiment of an invention.

FIG. 16 is a top view of an atomic layer deposition apparatus according to an embodiment of an invention.

FIGS. 17 and 18 are cross sectional views of an atomic layer deposition apparatus according to an embodiment of an invention.

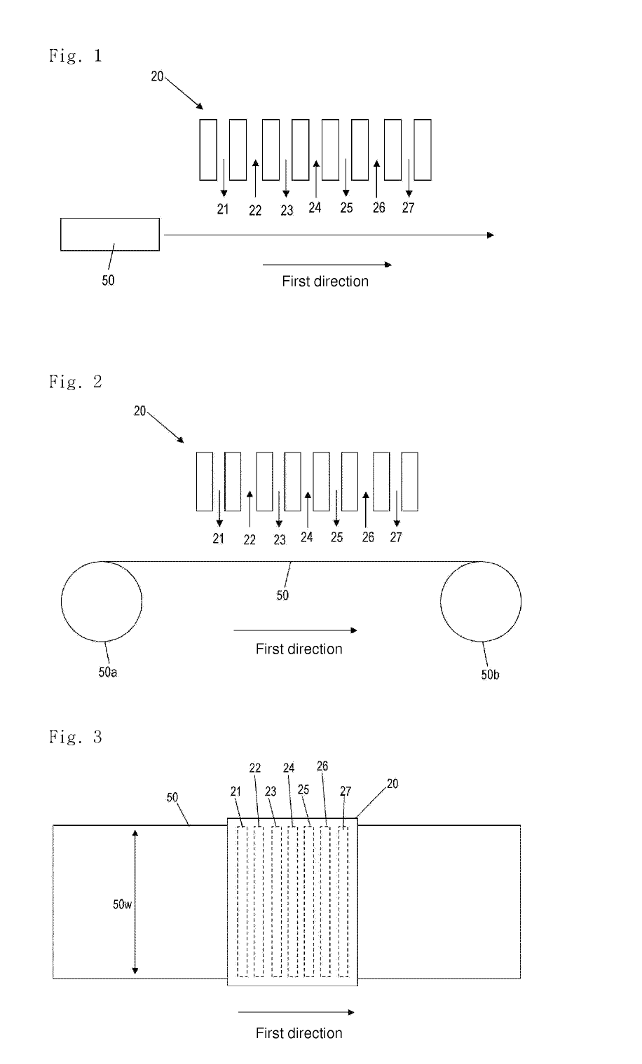

### DETAILED DESCRIPTION

With reference to the figures attached, embodiments according to the invention are described.

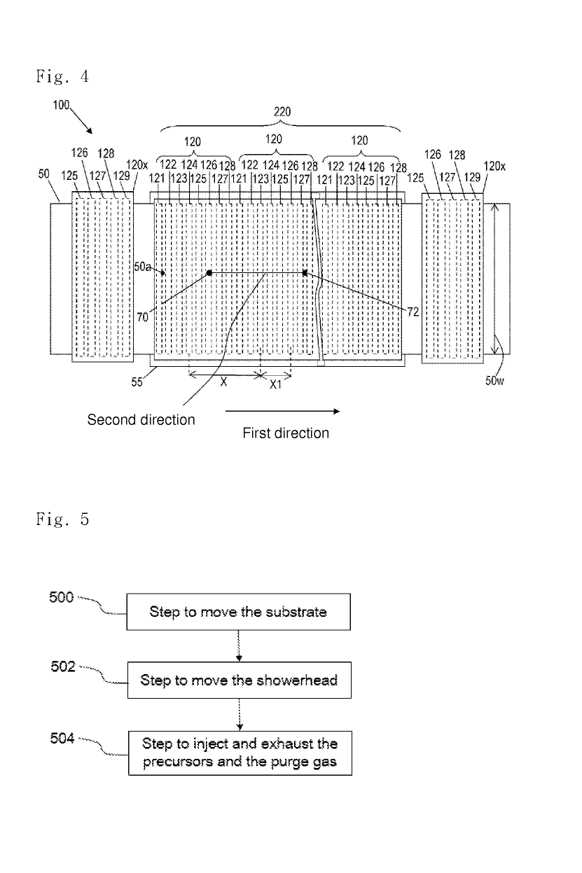

FIG. 4 is a top view of an apparatus 100 for depositing the atomic layers according to an embodiment of the invention. The apparatus 100 comprises a substrate moving mechanism (not shown in FIG. 4) to transport a substrate 50 along a first direction. The substrate moving mechanism is configured to control a moving speed of the substrate 50. The substrate 50 may be a flexible substrate.

The apparatus 100 further comprises a showerhead 220. The showerhead 220 comprises at least one injection unit 120. The injection unit 120 comprises a hole 123 for injecting a source precursor and a hole 127 for injecting a reactant precursor. The injection unit 120 further comprises at least one holes 122 and 124 for exhaust to exhaust the source precursor injected from the hole 123 for injecting the source precursor. The first and second holes 122 and 124 for exhaust may be disposed to sandwich the hole 123 for injecting the source precursor.

The injection unit 120 further comprises at least one holes 126 and 128 for exhaust to exhaust the reactant precursor injected from the hole 127 for injecting the reactant precursor. The third and fourth holes 126 and 128 for exhaust may be disposed to sandwich the hole 127 for injecting the reactant precursor.

The injection unit 120 further comprises at least holes 121 and 125 for injecting purge gas. The hole 123 for injecting the source precursor may be disposed between the first and second holes 121 and 125 for injecting the purge gas. The hole 127 for injecting the reactant precursor may be disposed between the second hole 125 for injecting the purge gas and the first hole 121 for injecting the purge gas of a neighboring injection unit 120. The purge gas injected from the holes 121 and 125 for injecting the purge gas is used to purge the source and reactant precursors adsorbed physically on a surface of the substrate.

The holes 121, 123, 125 and 127 for injecting the gases and the holes 122, 124, 126 and 128 for exhaust may extend such that they are parallel to a width 50w of the substrate. The width 50w of the substrate may be perpendicular to the first direction, which is the moving direction of the substrate.

The source and reactant precursors injected from the respective holes 123 and 127 for injecting the source and reactant precursors of the injection unit 120 may be separated such that they are not mixed by the purge gas injected from the holes for injecting the purge gas 121 and 125, which are disposed between the holes 123 and 127, and by the exhaust provided by the holes for exhaust 122, 124, 126 and 128, which are disposed between the holes 123 and 127.

The apparatus 100 may further comprise a substrate support 55, which is disposed under the showerhead 220. The substrate support 55 may further comprise a heating mechanism to heat the substrate 50.

The apparatus 100 may comprise a showerhead moving mechanism (not shown in FIG. 4). The showerhead moving mechanism is configured to reciprocate the showerhead 220 between first and second locations 70 and 72 along the second direction, The showerhead reciprocating mechanism 121 described in KR Patent Application Ser. No. 10-2012-0065954, which is incorporated in this patent application by reference, can be used as the showerhead moving mechanism. The second direction, which is the moving direction of the showerhead, can be the same with the first direction which is the moving direction of the substrate 50. According to an embodiment, an angle between the first and second directions may be less than 10 degree.

A distance between the first and second locations 70 and 72 may be equal to or greater than the distance X1 between the hole 123 for injecting the source precursor and the hole 127 for injecting the reactant precursor of the injection unit 120. The distance between the first and second locations 70 and 72 may be equal to or smaller than a pitch X of the injection units 120 or a distance between the holes for injecting the source precursor 123 of the neighboring injection units. The distance between the first and second locations 70 and 72 may be greater than the pitch X of the injection units 120. The pitch X, for example, may be between 30 and 100 mm. The pitch, for example, may be less than 30 mm.

The holes 121, 123,125 and 127 for injecting the gases and exhaust are coupled to respective sources of the gases (not shown in FIG. 4) and an exhaust pump (not shown in FIG. 4) through a gas injection control mechanism (not shown in FIG. 4). The gas injection control mechanism is configured to control injection of the source precursor, the reactant precursor and the purge gas and the exhaust of the injected gases through the holes for exhaust 122, 124, 126 and 128 while the showerhead 220 moves back and forth between the first and second locations 70 and 72.

The showerhead 220 deposits the atomic layers on the substrate 50 as it moves back and forth along the second direction. Referring to FIG. 4, a process of depositing the atomic layers on a point 50a on the substrate is described.

The point 50a on the substrate 50 passes the showerhead 220 as it moves along the first direction. While the point 50a passes the showerhead 220, the point 50a is exposed alternately to the source precursor injected from the hole 123 for injecting the source precursor of the showerhead 220, the purge gas injected from the hole 121, 125, 129 for injecting the purge gas of the showerhead 220, and the reactant precursor injected from the hole 127 for injecting the reactant precursor of the showerhead 220 by the reciprocations of the showerhead 220 along the second direction. Even when the point 50a is in a stationary state, the point 50a is exposed alternately to the source precursor, the purge gas and the reactant precursor by the reciprocations of the showerhead 220. The number of the atomic layers deposited on the point 50a is equivalent to the number that the point 50a is exposed to the source and reactant precursors.

In case that it takes 10 seconds for the point 50a to pass the showerhead 220 and the showerhead 220 reciprocates 20 times along the second direction during the 10 seconds, for example, the point 50a can be exposed to the source precursor and the reactant precursor 20 times at maximum, respectively, and therefore 20 atomic layers at maximum can be deposited on the point 50a.

In case that it takes 10 seconds for the point 50a to pass the showerhead 220 and the showerhead 220 reciprocates 40 times along the second direction during the 10 seconds, for another example, 40 atomic layers at maximum can be deposited on the point 50a.

In case that it takes 20 seconds for the point 50a to pass the showerhead 220 and the showerhead 220 reciprocates 40 times along the second direction during the 20 seconds, for another example, 40 atomic layers at maximum can be deposited on the point 50a.

According to the embodiments of the invention, the number of the atomic layers deposited on the point 50a can be controlled by controlling the time for the point 50a to pass the showerhead 220 or the moving speed of the substrate 50 as described above.

According to the embodiments of the invention, the number of the atomic layers deposited on the point 50a can be also controlled by the number of the reciprocations of the showerhead 220 along the second direction or the moving speed of the showerhead 220 while the substrate 50 passes the showerhead 220.

According to the conventional space-divided ALD, the number of the atomic layers deposited on the point 50a is decided only by the number of the injection units 120 of the showerhead 220 independently of the moving speed of the substrate 50. According to the embodiments of the invention, however, it is possible to deposit the greater number of the atomic layers than the number of injection units 120 of the showerhead 220. It is possible because that the holes 123 and 127 for injecting the source and reactant precursors can be transported to the point 50a alternately in addition to moving of the point 50a through the holes 123 and 127 for injecting the source and reactant precursors.

In case the showerhead 220 comprises 3 injection units 120, for example, 3 atomic layers are deposited on the point 50a while the point 50a passes the showerhead 220 one time according to the conventional space-divided ALD. According to the embodiments of the invention, however, more than 3, for example more than 10 atomic layers, can be deposited while the point 50a passes the showerhead 220 one time.

According to an embodiment of the invention, the ALD apparatus 100 may further comprise a second showerhead 120x, which is disposed after the showerhead 220. The second showerhead 120x may be coupled to the showerhead 220 and configured to reciprocate along the second direction.

The second showerhead 120x comprises a hole 127 for injecting the reactant precursor. The second showerhead 120x may further comprise at least one hole 126 and 128 for exhausting the reactant precursor injected from the hole 127 for injecting the reactant precursor. The first and second holes 126 and 128 for exhaust may be disposed to sandwich the hole 127 for injecting the reactant precursor. The second showerhead 120x may further comprise at least one hole 125 and 129 for injecting the purge gas. The hole 127 for injecting the reactant precursor may be disposed between the first and second holes 125 and 129 for injecting the purge gas.

The holes 123, 125 and 127 for injecting the gases and the holes 126 and 128 for exhaust of the second showerhead 120x are extended along the width direction 50w of the substrate like the holes for injecting the gases and exhaust of the showerhead 220.

In case that the substrate with the atomic layers deposited while the substrate passes the showerhead 220 comprises a surface coated with the source precursor and a surface coated with the reactant precursor, the second showerhead 120x can convert the surface coated with the source precursor to the surface coated with the reactant precursor by injecting the reactant precursor from the second showerhead 120x to the substrate 50.

According to an embodiment of the invention, the hole 127 for injecting the reactant precursor of the second showerhead 120x can be replaced with a hole 123 for injecting the source precursor. In this embodiment the substrate with the atomic layers deposited while the substrate passes the showerhead 220 comprises the surface coated with the source precursor and the surface coated with the reactant precursor, the second showerhead 120x can convert the surface coated with the reactant precursor to the surface coated with the source precursor.

The second showerhead 120x may be disposed before the showerhead 220 of the ALD apparatus 100. The second showerhead 120x may be disposed not only before but after the showerhead 220. The second showerhead 120x disposed before can coat the substrate surface with the source or reactant precursor before the substrate enters the showerhead 220.

FIG. 5 is a process flow diagram of a method to deposit the atomic layers at the ALD apparatus 100. Referring to FIGS. 4 and 5, an embodiment to deposit the atomic layers using the showerhead 220 at the ALD apparatus 100 comprises the following steps.

(1) a step 500 to move the substrate 50 along the first direction such that the substrate 50 passes near the injection surface of the showerhead 200,

(2) a step 502 to move the showerhead 220 back and forth between the first and second locations 70 and 72 along the second direction, and

(3) a step 504 to inject simultaneously the source precursor through the hole 123 for injecting the source precursor of the showerhead 220, the reactant precursor to the substrate 50 through the hole 127 for injecting the reactant precursor, and the purge gas to the substrate 50 through at least one of the holes 121 and 125 for injecting the purge gas, and to exhaust the source and reactant precursor and the purge gas through at least one of the holes 122, 124, 126 and 128 for exhaust during the showerhead moving step 502.

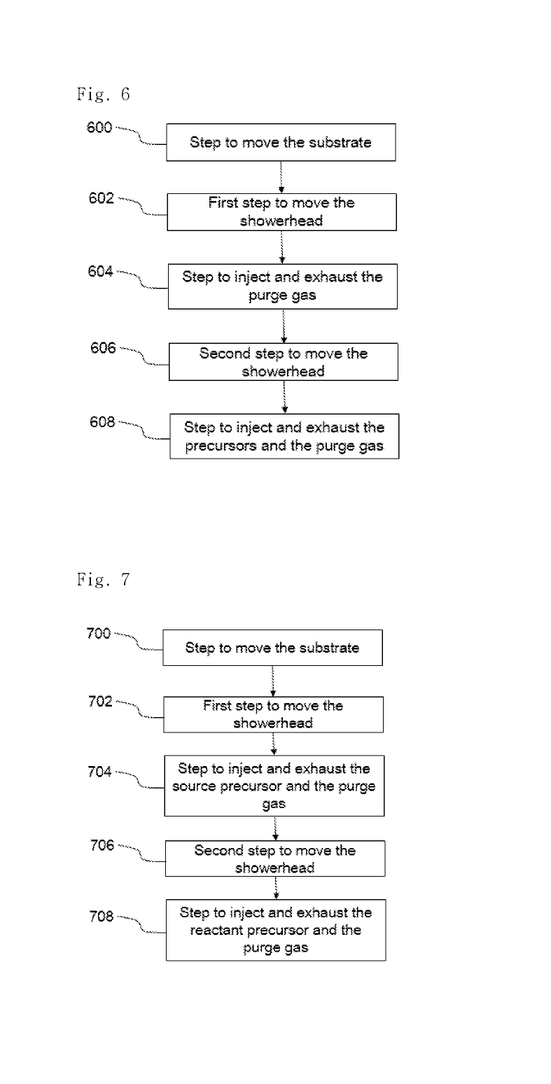

FIG. 6 is a process flow diagram of another method to deposit the atomic layers at the ALD apparatus 100. Referring to FIGS. 4 and 6, another embodiment to deposit the atomic layers using the showerhead 220 comprises the following steps.

(1) a step 600 to move the substrate 50 along the first direction such that the substrate 50 passes near the injection surface of the showerhead 200,

(2) a first moving step 602 to move the showerhead 220 from the first location 70 to the second location 72,

(3) a step 604 to stop injecting the source and reactant precursors through the holes 123 and 127 for injecting the source and reactant precursors, to purge the source precursor or the reactant precursor adsorbed physically on the surface of the substrate 50 by injecting the purge gas to the substrate 50 through at least one of the holes 121 and 125 for injecting the purge gas, and to exhaust the purge gas and the purged source or reactant precursor through at least one of the holes 122, 124, 126 and 128 for exhaust during the first moving step 602,

(4) a second moving step 606 to move the showerhead 220 from the second location 72 to the first location 70, and

(5) a step 608 to inject the source precursor through the hole 123 for injecting the source precursor of the showerhead 220, the reactant precursor at the same time to the substrate 50 through the hole 127 for injecting the reactant precursor, and the purge gas to the substrate 50 through at least one of the holes 121 and 125 for injecting the purge gas, and to exhaust the source and reactant precursor and the purge gas through at least one of the holes 122, 124, 126 and 128 for exhaust during the second moving step 606.

In this embodiment, consumption of the precursors can be decreased by injecting the source and reactant precursors during only one of the forward or reverse movements instead of injecting them consistently during the reciprocations of the showerhead 220. In this embodiment, high speed valves can be added in order to control the supply and cut-off of the source and reactant precursors at high speed.

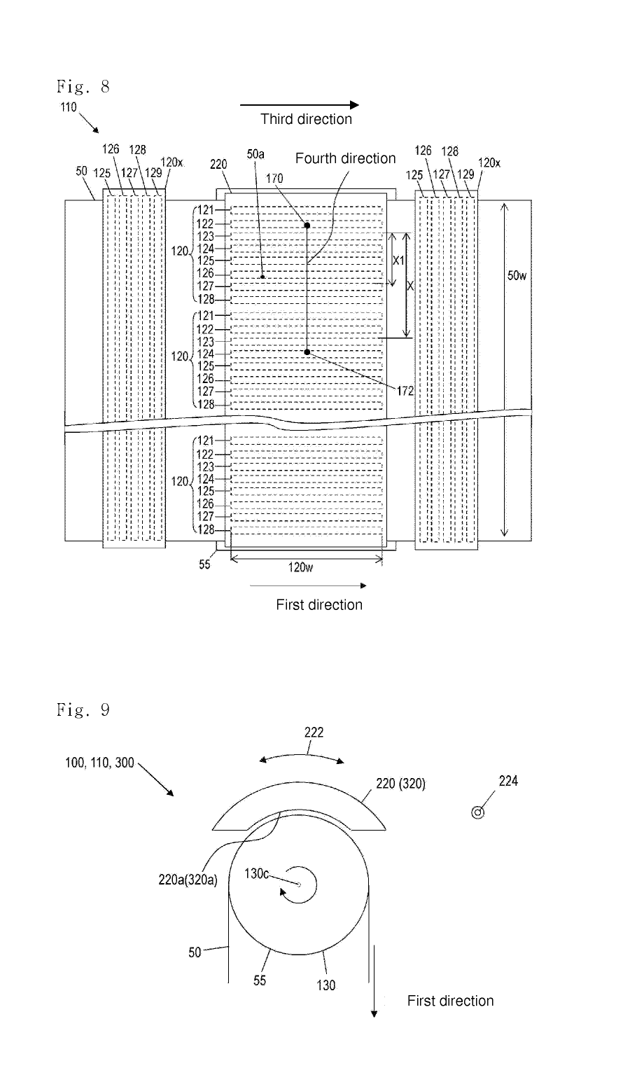

FIG. 7 is a process flow diagram of another method to deposit the atomic layers at the ALD apparatus 100. Referring to FIGS. 4 and 7, another embodiment to deposit the atomic layers using the showerhead 220 comprises the following steps.

(1) a step 700 to move the substrate 50 along the first direction such that the substrate 50 passes near the injection surface of the showerhead 220,

(2) a first moving step 702 to move the showerhead 220 between the first and second locations 70 and 72,

(3) a step 704 to stop injecting the reactant precursor through the hole 127 for injecting the reactant precursor, to inject the source precursor through the hole 123 for injecting the source precursor, to purge the residual source precursor adsorbed physically on the surface of the substrate 50 by injecting the purge gas to the substrate 50 through at least one of the holes 121 and 125 for injecting the purge gas, and to exhaust the purge gas and the purged residual source precursor through at least one of the holes 122, 124, 126 and 128 for exhaust during the first moving step 702,

(4) a second moving step 706 to move the showerhead 220 between the first and second locations 70 and 72, and

(5) a step 708 to stop injecting the source precursor through the hole 123 for injecting the source precursor, to inject the reactant precursor through the hole 127 for injecting the reactant precursor, to purge the residual reactant precursor adsorbed physically on the surface of the substrate 50 by injecting the purge gas to the substrate 50 through at least one of the holes 121 and 125 for injecting the purge gas, and to exhaust the purge gas and the purged residual reactant precursor through at least one of the holes 122, 124, 126 and 128 for exhaust during the second moving step 706.

In this embodiment the source and reactant precursors are injected sequentially with a time interval, which is different from the embodiments, which were described above, wherein they are injected simultaneously. By injecting them with the time interval, the possibility that the source and reactant precursors are mixed can be minimized or eliminated. In this embodiment, high speed valves can be used in order to control the supply and cut-off of the source and reactant precursors at high speed.

In the above embodiment, the moving directions of the showerhead 220 during the first and second moving steps 702 and 706 may be opposite. For example, the showerhead 220 moves from the first location 70 to the second location 72 during the first moving step 702, and the showerhead 220 moves from the second location 72 to the first location 70 during the second moving step 706.

In the above embodiment, the moving directions of the showerhead 220 during the first and second moving steps 702 and 706 may be the same. For example, the showerhead 220 moves from the first location 70 to the second location 72 during the first moving step 702, and the showerhead 220 moves from the first location 70 to the second location 72 during the second moving step 706. In this embodiment, the showerhead 220 does not inject the source and reactant precursors while the showerhead 220 moves from the second location 72 to the first location 70. However, the purge gas can be injected to the substrate 50 from the showerhead 220 and exhausted to through the showerhead 220.

In the above embodiments (FIGS. 5, 6 and 7) to deposit the atomic layers at the ALD apparatus 100, the second direction may be the same with the first direction. In addition, a distance between the first and second locations 70 and 72 may be equal to or greater than a distance X1 between the holes 123 and 127 for injecting the source and reactant precursors of the showerhead 220. A distance between the first and second locations 70 and 72 may be equal to or smaller than a pitch X of the injection units 120. The distance between the first and second locations 70 and 72 may be greater than the pitch X of the injection units 120.

The above embodiments (FIGS. 5. 6 and 7) may further comprise a step that the substrate 50 passes the second showerhead 120x after passing the showerhead 220. The surface of the substrate 50 is coated with the reactant or source precursor while it passes the second showerhead 120x.

The above embodiments may further comprise a step that the substrate 50 passes the second showerhead 120x before passing the showerhead 220. The surface of the substrate 50 is coated with the reactant or source precursor while it passes the second showerhead 120x.

Referring to FIG. 8, an ALD apparatus 110 according to an embodiment of the invention is described. FIG. 8 is a top view of the ALD apparatus 110. The ALD apparatus 110 is similar to the ALD apparatus 100 but an orientation and a reciprocating direction of the showerhead 220 is different,

The showerhead 220 is disposed at the ALD apparatus 110 such that the holes 121, 123, 125 and 127 for injecting the gases and the holes 122, 124, 126 and 128 for exhaust extend along a third direction. The third direction may be equal to the first direction which is the moving direction of the substrate 50. An angle between the first and third direction may be smaller than 10 degree.

The showerhead 220 is configured to move back and forth between first and second locations 170 and 172 along a fourth direction. The fourth direction may be perpendicular to the first direction which is the moving direction of the substrate. The fourth direction may be the same with the width direction 50w of the substrate 50. An angle between the fourth and first direction may be between 80 and 90 degree.

The showerhead 220 deposits the atomic layers on the substrate 50 as the showerhead 220 moves back and forth along the fourth direction. Referring to FIG. 8, a process of depositing the atomic layers on a point 50a on the substrate is described.

The point 50a on the substrate 50 passes the showerhead 220 as it moves along the first direction. While the point 50a passes the showerhead 220, the point 50a is exposed alternately to the source precursor injected from the hole 123 for injecting the source precursor of the showerhead 220, the purge gas injected from the hole 121, 125, 129 for injecting the purge gas of the showerhead 220, and the reactant precursor injected from the hole 127 for injecting the reactant precursor of the showerhead 220 by the reciprocations of the showerhead 220 along the fourth direction. The number of the atomic layers deposited on the point 50a is equivalent to the number that the point 50a is exposed to the source and reactant precursors.

In case that it takes 10 seconds for the point 50a to pass the width 120w of the injection units of the showerhead 220 and the showerhead 220 reciprocates along the fourth direction 20 times during the 10 seconds, for example, the point 50a can be exposed to the source precursor and reactant precursor 20 times at maximum, respectively, and 20 atomic layers at maximum can be deposited on the point 50a.

In case that it takes 10 seconds for the point 50a to pass the showerhead 220 and the showerhead 220 reciprocates 40 times along the fourth direction during the 10 seconds, for another example, 40 atomic layers at maximum can be deposited on the point 50a.

In case that it takes 20 seconds for the point 50a to pass the showerhead 220 and the showerhead 220 reciprocates 40 times along the second direction during the 20 seconds, for another example, 40 atomic layers at maximum can be deposited on the point 50a.

According to the embodiments of the invention, the number of the atomic layers deposited on the point 50a can be controlled by controlling the time for the point 50a to pass the showerhead 220 or the moving speed of the substrate 50 as described above.

According to the embodiments of the invention, the number of the atomic layers deposited on the point 50a can be also controlled by the number of the reciprocations of the showerhead 220 along the fourth direction or the moving speed of the showerhead 220 while the substrate 50 passes the showerhead 220.

Referring to FIGS. 5 and 8, an embodiment to deposit the atomic layers using the showerhead 220 at the ALD apparatus 110 comprises the following steps.

(1) a step 500 to move the substrate 50 along the first direction such that the substrate 50 passes near the injection surface of the showerhead 220,

(2) a step 502 to move the showerhead 220 back and forth between the first and second locations 170 and 172 along the fourth direction, and

(3) a step 504 to inject the source precursor through the hole 123 for injecting the source precursor of the showerhead 220, the reactant precursor at the same time to the substrate 50 through the hole 127 for injecting the reactant precursor, and the purge gas to the substrate 50 through at least one of the holes 121 and 125 for injecting the purge gas, and to exhaust the source and reactant precursor and the purge gas through at least one of the holes 122, 124, 126 and 128 for exhaust during the showerhead moving step 502.

Referring to FIGS. 6 and 8, another embodiment to deposit the atomic layers using the showerhead 220 at the ALD apparatus 110 comprises the following steps.

(1) a step 600 to move the substrate 50 along the first direction such that the substrate 50 passes near the injection surface of the showerhead 220,

(2) a first moving step 602 to move the showerhead 220 from the first location 170 to the second location 172,

(3) a step 604 to stop injecting the source and reactant precursors through the holes 123 and 127 for injecting the source and reactant precursors, to purge the source precursor or the reactant precursor adsorbed physically on the surface of the substrate 50 by injecting the purge gas to the substrate 50 through at least one of the holes 121 and 125 for injecting the purge gas, and to exhaust the purge gas and the purged source and reactant precursors through at least one of the holes 122, 124, 126 and 128 for exhaust during the first moving step 602,

(4) a second moving step 606 to move the showerhead 220 from the second location 172 to the first location 170, and

(5) a step 608 to inject the source precursor through the hole 123 for injecting the source precursor of the showerhead 220, the reactant precursor at the same time to the substrate 50 through the hole 127 for injecting the reactant precursor, and the purge gas to the substrate 50 through at least one of the holes 121 and 125 for injecting the purge gas, and to exhaust the source and reactant precursor and the purge gas through at least one of the holes 122, 124, 126 and 128 for exhaust during the second moving step 606.

Referring to FIGS. 7 and 8, another embodiment to deposit the atomic layers using the showerhead 220 comprises the following steps.

(1) a step 700 to move the substrate 50 along the first direction such that the substrate 50 passes near the injection surface of the showerhead 200,

(2) a first moving step 702 to move the showerhead 220 between the first and second locations 170 and 172,

(3) a step 704 to stop injecting the reactant precursor through the hole 127 for injecting the reactant precursor, to inject the source precursor through the hole 123 for injecting the source precursor, to purge the residual source precursor adsorbed physically on the surface of the substrate 50 by injecting the purge gas to the substrate 50 through at least one of the holes 121 and 125 for injecting the purge gas, and to exhaust the purge gas and the purged residual source precursor through at least one of the holes 122, 124, 126 and 128 for exhaust during the first moving step 702,

(4) a second moving step 706 to move the showerhead 220 between the first and second locations 170 and 172, and

(5) a step 708 to stop injecting the source precursor through the hole 123 for injecting the source precursor, to inject the reactant precursor through the hole 127 for injecting the reactant precursor, to purge the residual reactant precursor adsorbed physically on the surface of the substrate 50 by injecting the purge gas to the substrate 50 through at least one of the holes 121 and 125 for injecting the purge gas, and to exhaust the purge gas and the purged residual reactant precursor through at least one of the holes 122, 124, 126 and 128 for exhaust during the second moving step 706.

In the above embodiment, the moving directions of the showerhead 220 during the first and second moving steps 702 and 706 may be opposite. For example, the showerhead 220 moves from the first location 170 to the second location 172 and during the first moving step 702, and the showerhead 220 moves from the second location 172 to the first 170 during the second moving step 706.

In the above embodiment, the moving directions of the showerhead 220 during the first and second moving steps 702 and 706 may be the same. For example, the showerhead 220 moves from the first location 170 to the second location 172 during the first moving step 702, and the showerhead 220 moves from the first location 170 to the second 172 during the second moving step 706. In this embodiment, the showerhead 220 does not inject the source and reactant precursors while the showerhead 220 moves from the second location 172 to the first location 170. However, the purge gas can be injected to the substrate 50 and the purged gas can be exhausted through the showerhead 220.

In the above embodiments, the second direction may be the same with the first direction. In addition, a distance between the first and second locations 170 and 172 may be equal to or greater than a distance X1 between the holes 123 and 127 for injecting the source and reactant precursors respectively. A distance between the first and second locations 170 and 172 may be equal to or smaller than a pitch X of the injection units 120. The distance between the first and second locations 170 and 172 may be greater than the pitch X of the injection units 120.

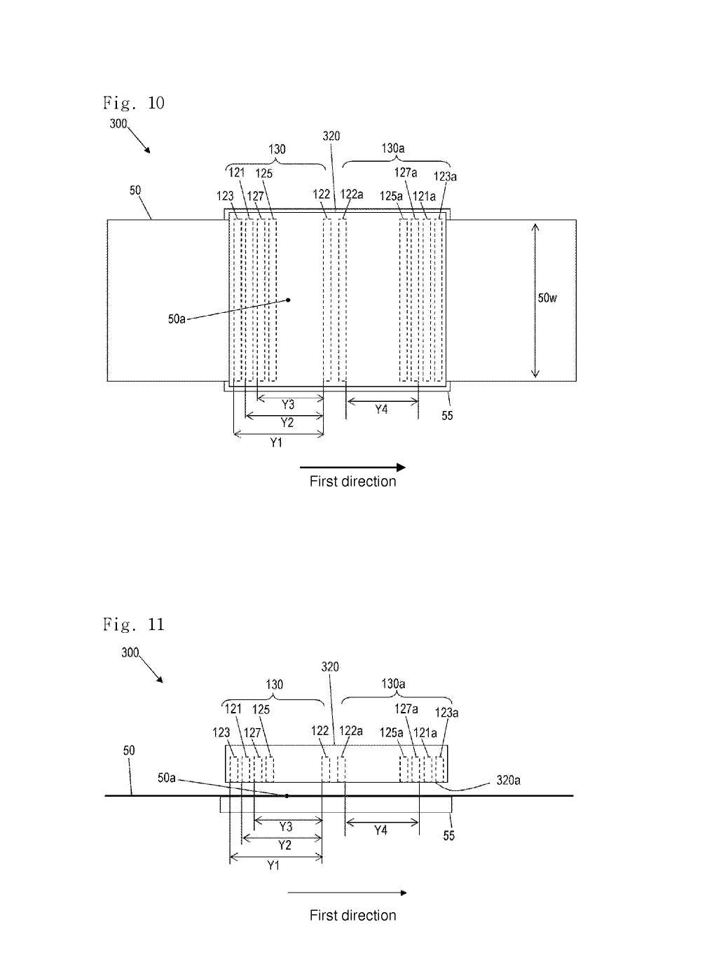

According to an embodiment of the invention, the ALD apparatus 100 and 110 illustrated in FIGS. 4 and 8 may comprise a substrate support 55, which has a shape of a roller 130. FIG. 9 is a side view of the ALD apparatus 100 and 110 comprising the substrate support 55, which has the shape of the roller 130.

The roller 130 may be configured to rotate about a central axis 130c. The substrate 50 is supported on the roller 130 such that the substrate 50 faces the showerhead 220. The substrate 50 moves along the first direction by a substrate moving mechanism (not shown in FIG. 9). A gas injection surface 220a of the showerhead 220 is disposed about the roller 130 and curved along a circumference of the roller 130 such that it surrounds the roller 130.

Referring to the ALD apparatus 100 in FIG. 9, in an embodiment where the injection units of the showerhead 220 extends along the substrate width 50w which is parallel to the central axis 130c of the roller 130, the showerhead 220 illustrated in FIG. 9 is configured to pivot back and forth 222 about the axis 130c of the roller 130 and inject the precursors and the purge gas to the substrate 50 and exhaust them. In this embodiment, therefore, the pivoting direction 222 corresponds to the reciprocating direction of the showerhead 220 in the ALD apparatus 100 of FIG. 9, which is the second direction.

Referring to the ALD apparatus 110 illustrated in FIG. 9, in an embodiment where the injection units of the showerhead 220 extends along the substrate moving direction which is the first direction like in the ALD apparatus 100 in FIG. 8, the showerhead 220 illustrated in FIG. 9 is configured to move linearly back and forth 224 parallel to the central axis 130c of the roller 130 and inject the precursors and the purge gas to the substrate 50 and exhaust them. In this embodiment, the linear back and forth moving direction 224 corresponds to the reciprocating direction of the showerhead 220 in the ALD apparatus 110 of FIG. 9, which is the fourth direction.

Methods to deposit the atomic layers in the apparatus 100 and 110 in FIG. 9 are similar to the methods described with reference to FIGS. 4, 5, 6, 7 and 8 and a difference is that the injection surface 220a and 320a of the showerhead 220 is curved.

Referring to FIGS. 10 and 11, an ALD apparatus 300 according to an embodiment of the invention is described. FIGS. 10 and 11 are top and side views of the ALD apparatus 300, respectively. The ALD apparatus 300 may comprise a substrate moving mechanism (not shown in FIG. 10), which is configured to transport the substrate 50 along the first direction. The first direction may be perpendicular to the width 50w of the substrate. The ALD apparatus 300 further comprises a showerhead 320 disposed about the substrate 50. A substrate support 55 configured to support the substrate 50 may be disposed under the showerhead 320.

The showerhead 320 comprises a first injection unit 130. The first injection unit 130 comprises a hole 123 for injecting the source precursor, a hole 127 for injecting the reactant precursor, and a hole 122 for exhaust. The hole 127 for injecting the reactant precursor may be disposed between the hole 123 for injecting the source precursor and the hole 122 for exhaust. The hole 123 for injecting the source precursor may be disposed between the hole 127 for injecting the reactant precursor and the hole 122 for exhaust. The first injection unit 130 is configured to exhaust the source and reactant precursors injected from the holes 123 and 127 for injecting the source and reactant precursors through the hole 122 for exhaust.

The first injection unit 130 further comprises a hole 121 for injecting the purge gas. The hole 121 for injecting the purge gas may be disposed between the hole 123 for injecting the source precursor and the hole 127 for injecting the reactant precursor. The hole 121 for injecting the purge gas may be disposed at an opposite side of the hole 122 for exhaust across the holes 123 and 127 for injecting the source and reactant precursors. The first injection unit 130 extends along the width direction 50w of the substrate and may further comprise a second hole 125 for injecting the purge gas, which is disposed between the hole 127 for injecting the reactant precursor and the hole 122 for exhaust. The first injection unit 130 is configured such that the purge gas injected from the holes 121 and 125 for injecting the purge gas is exhausted through the hole 122 for exhaust.

The step that the first injection unit 130 of the showerhead 320 injects and exhausts the source precursor, the purge gas, and the reactant precursor comprises the following 4 steps.

(1) a source precursor injecting step 800 where the source precursor is injected from the hole 123 for injecting the source precursor and exhausted through the hole 122 for exhaust,

(2) a purge gas injecting step 802 where the purge gas is injected from the hole 121 or 121 and 125 for injecting the purge gas and exhausted through the hole 122 for exhaust,

(3) a reactant precursor injecting step 804 where the reactant precursor is injected from the hole 127 for injecting the reactant precursor and exhausted through the hole 122 for exhaust, and

(4) a second purge gas injecting step 806 where the purge gas is injected from the hole 121 or 121 and 125 for injecting the purge gas and exhausted through the hole 122 for exhaust.

At the source precursor injecting step 800, the source precursor coats the surface of the substrate 50 in a section Y1, which is between the hole 123 for injecting the source precursor and the hole 122 for exhaust, as the source precursor travels to the hole 122 for exhaust through the space between the showerhead 320 and the substrate 50.

At the first purge gas injecting step 802, the purge gas purges the residual source precursors adsorbed physically on the surface of the substrate 50 in a section Y2, which is between the hole 121 for injecting the purge gas and the hole 122 for exhaust, as the purge gas travels to the hole 122 for exhaust through the space between the showerhead 320 and the substrate 50.

At the reactant precursor injecting step 804, the reactant precursor coats the surface of the substrate 50 in a section area Y3, which is between the hole 127 for injecting the reactant precursor and the hole 122 for exhaust, as the reactant precursor travels to the hole 122 for exhaust through the space between the showerhead 320 and the substrate 50.

At the second purge gas injecting step 806, the purge gas purges the residual source precursors adsorbed physically on the surface of the substrate 50 in a section Y2, which is between the hole 121 for injecting the purge gas and the hole 122 for exhaust, as the purge gas travels to the hole 122 for exhaust through the space between the showerhead 320 and the substrate 50.

A point 50a on the substrate 50 can be repeatedly exposed to the cycles of the above 4 steps while the point 50a passes the section Y3, which is between the hole 127 for injecting the reactant precursor 127 and the hole 122 for exhaust, and therefore the atomic layers can be deposited on the point 50a by the repeated exposures.

In case that it takes 10 seconds for the point 50a to pass the section Y3, which is between the hole 127 for injecting the reactant precursor 127 and the hole 122 for exhaust, and the showerhead 320 repeats the above 4 step cycle 20 times during the 10 seconds, the point 50a can be exposed to the source precursor and the reactant precursor 20 times, respectively, and therefore 20 atomic layers can be deposited on the point 50a.

In case that it takes 10 seconds for the point 50a to pass the section Y3, which is between the hole 127 for injecting the reactant precursor 127 and the hole 122 for exhaust, and the showerhead 320 repeats the above 4 step cycle 40 times during the 10 seconds, 40 atomic layers can be deposited on the point 50a.

In case that it takes 20 seconds for the point 50a to pass the section Y3, which is between the hole 127 for injecting the reactant precursor 127 and the hole 122 for exhaust, and the showerhead 320 repeats the above 4 step cycle 40 times during the 10 seconds, 40 atomic layers can be deposited on the point 50a.

According to the embodiments of the invention, the number of the atomic layers deposited on the point 50a can be controlled by controlling the time for the point 50a to pass the showerhead 320, a cycle time of the 4 steps or the number of the cycles as described above.

According to an embodiment of the invention, the showerhead 320 of the ALD apparatus 300 can further comprise a second injection unit 130a as illustrated in FIGS. 10 and 11.

The second injection unit 130a comprises a hole 123a for injecting the source precursor, a hole 127a for injecting the reactant precursor and a hole 122a for exhaust, which extend along the width 50w of the substrate 50. The hole 127a for injecting the reactant precursor may be disposed between the hole 123a for injecting the source precursor and the hole 122a for exhaust. The hole 123a for injecting the source precursor may be disposed between the hole 127a for injecting the reactant precursor and the hole 122a for exhaust. The second injection unit 130a is configured to exhaust the source and reactant precursors injected from the holes 123a and 127a for injecting the source and reactant precursors, respectively, through the hole 122a for exhaust.

The second injection unit 130a further comprises a hole 121a for injecting the purge gas, which extends along the width 50w of the substrate 50. The hole 121a for injecting the purge gas may be disposed between the hole 123a for injecting the source precursor and the hole 127a for injecting the reactant precursor. The hole 121a for injecting the purge gas may be disposed at an opposite side of the hole 122a for exhaust across the holes 123a and 127a for injecting the source and reactant precursors. The second injection unit 130a may further comprise a second hole 125a for injecting the purge gas, which extends along the width direction 50w of the substrate and is disposed between the hole 127a for injecting the reactant precursor and the hole 122a for exhaust. The second injection unit 130a is configured such that the purge gas injected from the holes 121a and 125a for injecting the purge gas is exhausted through the hole 122a for exhaust.

The hole 122a for exhaust of the second injection unit 130a is disposed adjacent to the hole 122 for exhaust of the first injection unit 130, and the hole 123a for injecting the source precursor, the hole 127a for injecting the reactant precursor and the holes 121a and 125a for injecting the purge gas may be disposed at an opposite side of the first injection unit 130 across the hole 122a for exhaust.

According to an embodiment of the invention, the hole 122a for exhaust of the second injection unit 130a can be replaced with the hole 122 for exhaust of the first injection unit 130. The hole 122a for exhaust of the second injection unit 130a can be merged with the hole 122 for exhaust of the first injection unit 130.

The second injection unit 130a is also configured to repeat the above 4 cycles 800, 802, 804 and 806 like the first injection unit 130.

At the source precursor injecting step 800 of the above 4 step cycle, the source precursor is injected simultaneously from the holes 123 and 123a for injecting the source precursor of the first and second injection units 130 and 130a.

At the purge gas injecting step 802 of the above 4 step cycle, the purge gas is injected simultaneously from the holes 121, 125, 121a and 125a for injecting the purge gas of the first and second injection units 130 and 130a.

At the reactant precursor injecting step 804 of the 4 step cycle, the reactant precursor is injected simultaneously from the holes 127 and 127a for injecting the reactant precursor of the first and second injection units 130 and 130a.

At the second purge gas injecting step 806 of the 4 step cycle, the purge gas is injected simultaneously from the hole 121, 125, 121a and 125a for injecting the purge gas of the first and second injection units 130 and 130a.

Additional atomic layers are deposited on the point 50a, which already has the atomic layers deposited while it passed the section Y3 of the first injection unit 130, as the point 50a is additionally and repeatedly exposed to the 4 step cycles by the second injection unit 130a while the point 50a passes the section Y4, which is between the hole 122a for exhaust and the hole 127a for injecting the reactant precursor of the second injection unit 130a. By adding the second injection unit 130a, throughput of the ALD apparatus 300 can be improved.

According to an embodiment of the invention, an injection surface 320a of the showerhead 320 can be curved along the circumference of the roller 130 as illustrated in FIG. 9 in case that the substrate support 55 has the shape of the roller 130 as illustrated in FIG. 9.

According to an embodiment of the invention, the ALD apparatuses 100, 110 and 300 can be installed in a vacuum chamber. The ALD apparatuses 100, 110, 300 can be configured to stop exhausting from the chamber after the chamber with the substrate loaded reaches a vacuum and further configured to exhaust only through a exhaust pump coupled to the holes 122, 124, 126 and 128 for exhaust of the showerhead 220 and 320

According to an embodiment of the invention, the ALD apparatus 100 and 110 illustrated in FIGS. 4 and 8 may comprise a bottom showerhead 120y as a replacement of the substrate support 55 disposed under the substrate 50. The additional bottom showerhead 120y is coupled to the same showerhead moving mechanism of the showerhead 220. The showerhead 220 and the bottom showerhead 120y are configured to reciprocate along the second and fourth directions, respectively. The bottom showerhead 120y is configured to deposit the atomic layers on a bottom surface of the substrate in the same manner with the showerhead 220. According to the embodiment, the atomic layers can be deposited on the top and bottom surfaces of the substrate 50 simultaneously as the substrate 50 passes between the showerhead 220 and the bottom showerhead 120y. In the embodiment, a device to heat the substrate may be disposed before the showerhead to preheat the substrate before it moves under the showerhead.

According to an embodiment of the invention, the ALD apparatus 300 illustrated in FIG. 10 may comprise a bottom showerhead 320y as a replacement of the substrate support 55 disposed under the substrate 50. The additional bottom showerhead 320y is configured to deposit the atomic layers on the bottom surface of the substrate in the same manner with the showerhead 320. According to the embodiment, the atomic layers can be deposited on the top and bottom surfaces of the substrate 50 simultaneously as the substrate 50 passes between the top showerhead 320 and the bottom showerhead 320y. In the embodiment, a device to heat the substrate may be disposed before the showerhead.

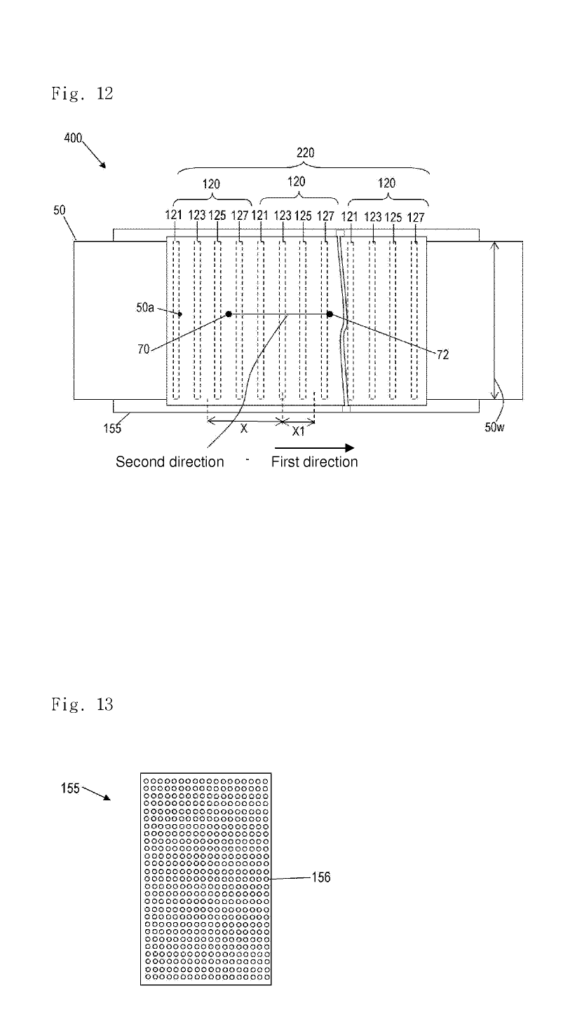

FIG. 12 is a top view of an ALD apparatus 400 according to an embodiment of the invention. The ALD apparatus 400 is a modified embodiment of the ALD apparatus 100 described with reference to FIG. 4. The ALD apparatus 400 can be used to deposit the atomic layers on a gas permeable substrate 50. For example, it can be used to deposit the atomic layers on a porous separator film of the lithium ion battery made of plastic materials such as polyethylene, polypropylene and etc. It can be also used to deposit the atomic layers on a gas permeable textile.

The showerhead 220 of the ALD apparatus 400 does not comprise the holes for exhaust 122, 124, 126 and 128 and the substrate support 55 is replaced with a plate for exhaust 155, which are the differences from the ALD apparatus 100. The injection units 120 of the showerhead 220 in the ALD apparatus 400 comprises the hole 123 for injecting the source precursor, the hole 127 for injecting the reactant precursor and at least one hole 121 and 125 for injecting the purge gas but does not comprise a hole for exhaust. The source and reactant precursors and the purge gas injected from the showerhead 220 are exhausted through the substrate 50 to the plate for exhaust 155. The showerhead 220 reciprocates between the first and second locations 70 and 72 along the second direction and injects the source and reactant precursors and the purge gas to the substrate 50.

FIG. 13 is a top view of the plate for exhaust 155. The plate for exhaust 155 is disposed at an opposite side of the showerhead 220 across the substrate 50. The plate for exhaust 155 comprises at least one hole 156 for exhaust. The hole for exhaust 156 is coupled to an exhaust pump (not shown in FIG. 13). The hole for exhaust 156 may be designed to have circular, rectangular and slit shapes on the top view and may have linear, curved or tilted lines on a cross-sectional view.

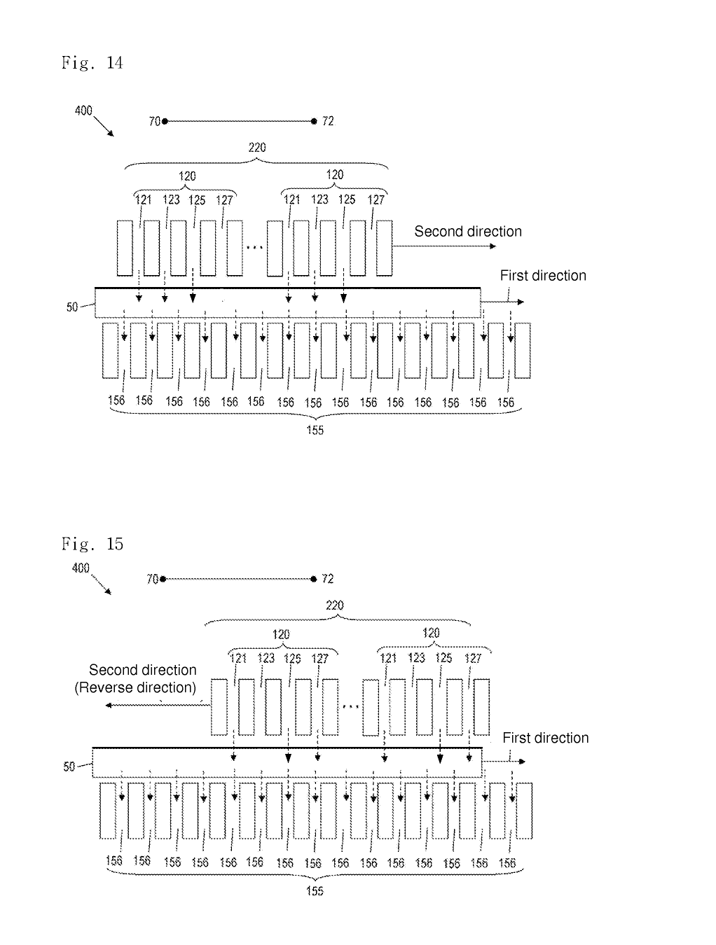

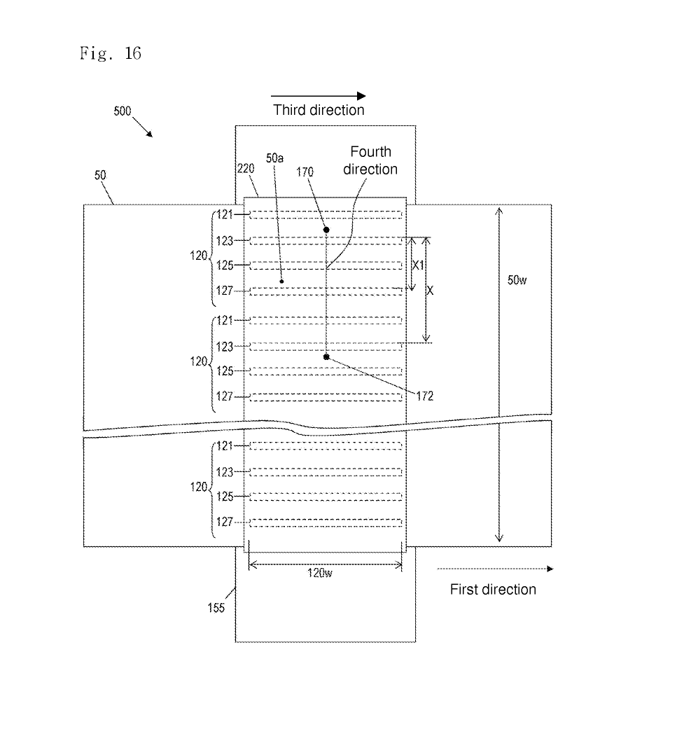

Referring to FIGS. 14 and 15, a method to deposit the atomic layers on the substrate 50 using the ALD apparatus 400 is described. FIGS. 14 and 15 are cross-sectional views of the showerhead 220 when it is located at the first and second locations 70 and 72, respectively. The dashed arrows shown in FIGS. 14 and 15 shows the flows of the fluids injected from the showerhead 220 and exhausted through the substrate 50 to the plate for exhaust 155.

At the first location 70, referring to FIG. 14, the source precursor and the purge gas are injected to the substrate 50 from the hole 123 for injecting the source precursor and the hole 121 and 125 for injecting the purge gas, respectively. The injected source precursor and the purge gas are exhausted to the plate for exhaust 155 through the substrate 50. Inside of the substrate 50 is coated with the source precursor while the source precursor passes the substrate 50. As the showerhead 220 moves to the second location 72 along the second direction, other section of the substrate 50 is coated with the source precursor and purged with the purge gas. The source precursor and the purge gas injected during the moving of the showerhead 220 are exhausted to the plate for exhaust 155. The showerhead 220 is moved at a first velocity V1 and a moving distance is similar to the pitch X of the neighboring injection units 120. According to an embodiment, the moving distance is not grater than 2 times of the pitch X.

At the second location 72, referring to FIG. 15, the injection of the source precursor through the hole 123 for injecting the source precursor is stopped and the reactant precursor and the purge gas are injected from the hole 127 for injecting the reactant precursor and the hole 121 and 125 for injecting the purge gas, respectively. The injected reactant precursor and the purge gas are exhausted through the substrate 50 to the plate for exhaust 155. As the showerhead 220 moves from the second location 72 to the first location 70 along the second direction, other section of the substrate 50 is coated with the source precursor and purged with the purge gas. The reactant precursor and the purge gas injected during the moving of the showerhead 220 are exhausted to the plate for exhaust 155. The showerhead 220 is moved at a second velocity V2. The first and second moving velocities V1 and V2 may be the same or different.

Referring to FIGS. 12 and 7, an embodiment to deposit the atomic layers using the ALD apparatus 400 comprises the following steps.

(1) a step 700 to dispose the substrate 50 about the gas injection surface of the showerhead 220,

(2) a first moving step 702 to move the showerhead 220 between the first and second locations 70 and 72, and

(3) a step 704 to stop injecting the reactant precursor through the hole 127 for injecting the reactant precursor, to inject the source precursor through the hole 123 for injecting the source precursor, to purge the residual source precursor adsorbed physically on the surface of the substrate 50 by injecting the purge gas to the substrate 50 through at least one of the holes 121 and 125 for injecting the purge gas, and to exhaust the purge gas and the source precursor through the hole 156 of the plate 155 for exhaust during the first moving step 702,

(4) a second moving step 706 to move the showerhead 220 between the first and second locations 70 and 72, and

(5) a step 708 to stop injecting the source precursor through the hole 123 for injecting the source precursor, to inject the reactant precursor through the hole 127 for injecting the reactant precursor, to purge the residual reactant precursor adsorbed physically on the surface of the substrate 50 by injecting the purge gas to the substrate 50 through at least one of the holes 121 and 125 for injecting the purge gas, and to exhaust the purge gas and the reactant precursor through the plate 155 for exhaust during the second moving step 706.

In the embodiment the source and reactant precursors are sequentially injected with a time interval. By injecting with the time interval the possibility that the source and reactant precursors are mixed can be minimized or eliminated.

In the embodiment, a purge step 705 can be added between the first and second moving steps 702 and 706. During the purge step 705, moving of the showerhead 220 and the injection of the source and reactant precursors are stopped and the purge gas is injected from the holes 121 and 125 for injecting the purge gas. The purge gas can be injected as well from the holes 123 and 127 for injecting the source and reactant precursors, respectively.

In the embodiment, the moving directions of the showerhead 220 during the first and second moving steps 702 and 706 may be opposite. For example, the showerhead 220 moves from the first location 70 to the second location 72 during the first moving step 702, and the showerhead 220 moves from the second location 72 to the first 70 during the second moving step 706.

In the embodiment, the moving directions of the showerhead 220 during the first and second moving steps 702 and 706 may be the same. For example, the showerhead 220 moves from the first location 70 to the second location 72 during the first and second moving steps 702 and 706. In this embodiment, a third moving step to move the showerhead 220 from the second location 72 to the first location 70 is further comprised. During the third moving step, the source and reactant precursors are not injected from the showerhead 220 to the substrate 50. The purge gas, however, can be injected from the showerhead 220 to the substrate 50 and the purged gas is exhausted through the plate 155 for exhaust.

FIG. 16 is a top view of an ALD apparatus 500 according to an embodiment of the invention. The ALD apparatus 500 is a modified embodiment of the ALD apparatus 110 described with reference to FIG. 8. The ALD apparatus 500 can be used to deposit the atomic layers on a gas permeable substrate 50.

The differences of the ALD apparatus 500 from the ALD apparatus 110 are that the showerhead 220 of the ALD apparatus 500 does not comprise the holes for exhaust 122, 124, 126 and 128 and the substrate support 55 is replaced with the plate for exhaust 155. The injection units 120 of the showerhead 220 in the ALD apparatus 500 comprise the hole 123 for injecting the source precursor, the hole 127 for injecting the reactant precursor and at least one hole 121 and 125 for injecting the purge gas but does not comprise a hole for exhaust. The source and reactant precursors and the purge gas injected from the showerhead 220 are exhausted through the substrate 50 to the plate for exhaust 155. The showerhead 220 reciprocates between the first and second locations 170 and 172 along the fourth direction and injects the source and reactant precursors and the purge gas to the substrate 50. The fourth direction is parallel to the width 50w of the substrate.

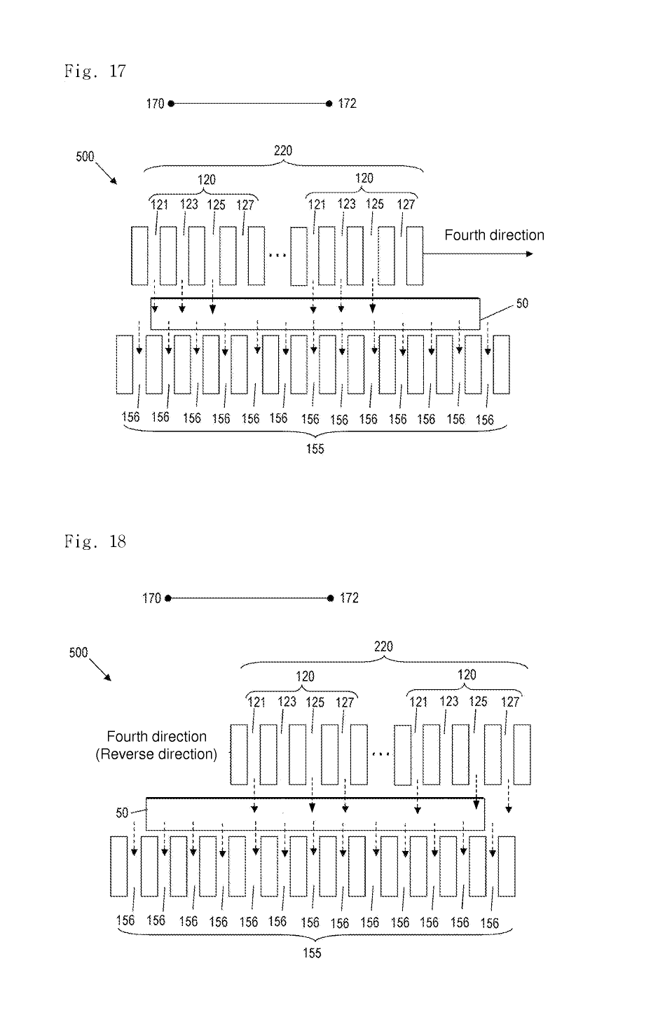

Referring to FIGS. 17 and 18, a method to deposit the atomic layers on the substrate 50 using the ALD apparatus 500 is described. FIGS. 17 and 18 are cross-sectional views of the showerhead 220 when it is located at the first and second locations 170 and 172, respectively. The dashed arrows shown in FIGS. 17 and 18 shows the flow of the fluids injected from the showerhead 220 and exhausted through the substrate 50 to the hole 156 for exhaust.

At the first location 170, referring to FIG. 17, the source precursor and the purge gas are injected to the substrate 50 from the hole 123 for injecting the source precursor and the hole 121 and 125 for injecting the purge gas, respectively. The injected source precursor and the purge gas are exhausted through the substrate 50 to the plate for exhaust 155. As the showerhead 220 moves to the second location 172 along the fourth direction, other section of the substrate 50 is coated with the source precursor and purged with the purge gas. The source precursor and the purge gas injected during the moving of the showerhead 220 are exhausted through the plate for exhaust 155. A moving distance of the showerhead 220 is similar to the pitch X of the neighboring injection units 120. According to an embodiment, the moving distance is not grater than 2 times of the pitch X.

At the second location 172, referring to FIG. 18, the injection of the source precursor through the hole 123 for injecting the source precursor is stopped and the reactant precursor and the purge gas are injected from the hole 127 for injecting the reactant precursor and the hole 121 and 125 for injecting the purge gas, respectively. The injected reactant precursor and the purge gas are exhausted through the substrate 50 to the plate for exhaust 155. As the showerhead 220 moves from the second location 172 to the first location 170, other section of the substrate 50 is coated with the source precursor and purged with the purge gas. The reactant precursor and the purge gas injected during the moving of the showerhead 220 are exhausted through the plate for exhaust 155.

Referring to FIGS. 16 and 7, an embodiment to deposit the atomic layers at the ALD apparatus 500 comprises the following steps.

(1) a step 700 to dispose the substrate about the gas injection surface of the showerhead 220,

(2) a first moving step 702 to move the showerhead 220 between the first and second locations 170 and 172, and

(3) a step 704 to stop injecting the reactant precursor through the hole 127 for injecting the reactant precursor, to inject the source precursor through the hole 123 for injecting the source precursor, to purge the residual source precursor adsorbed physically on the surface of the substrate 50 by injecting the purge gas to the substrate 50 through at least one of the holes 121 and 125 for injecting the purge gas, and to exhaust the purge gas and the source precursor through the hole 156 for exhaust of the plate 155 for exhaust during the first moving step 702,

(4) a second moving step 706 to move the showerhead 220 between the first and second locations 170 and 172, and

(5) a step 708 to stop injecting the source precursor through the hole 123 for injecting the source precursor, to inject the reactant precursor through the hole 127 for injecting the reactant precursor, to purge the residual reactant precursor adsorbed physically on the surface of the substrate 50 by injecting the purge gas to the substrate 50 through at least one of the holes 121 and 125 for injecting the purge gas, and to exhaust the purge gas and the reactant precursor through the plate 155 for exhaust during the second moving step 706.

In the embodiment, a purge step 705 can be added between the first and second moving steps 702 and 706. During the purge step 705, moving of the showerhead 220 and the injection of the source and reactant precursors are stopped and the purge gas is injected from the holes 121 and 125 for injecting the purge gas. The purge gas can be injected as well from the holes 123 and 127 for injecting the source and reactant precursors, respectively.

In the embodiment, the moving directions of the showerhead 220 during the first and second moving steps 702 and 706 may be opposite. For example, the showerhead 220 moves from the first location 170 to the second location 172 during the first moving step 702, and the showerhead 220 moves from the second location 172 to the first 170 during the second moving step 706.

In the embodiment, the moving directions of the showerhead 220 during the first and second moving steps 702 and 706 may be the same. For example, the showerhead 220 moves from the first location 170 to the second location 172 during the first and second moving steps 702 and 706. In this embodiment, a third moving step to move the showerhead 220 from the second location 172 to the first location 170 is further comprised. During the third moving step, the source and reactant precursors are not injected from the showerhead 220 to the substrate 50. The purge gas, however, can be injected from the showerhead 220 to the substrate 50 and the purged gas is exhausted to the plate 155 for exhaust.

In the ALD apparatuses 100 and 400, according to an embodiment of the invention, the substrate 50 may move continuously along the first direction while the showerhead 220 reciprocates between the first and second locations 70 and 72 and injects the source and reactant precursors alternately. According to another embodiment of the invention, the substrate 50 may be stationary while the showerhead 220 reciprocates between the first and second locations 70 and 72 and injects the source and reactant precursors alternately. In this embodiment the substrate 50 is moved after a desired number of the atomic layers are deposited on a specific section of the substrate 50.

According to an embodiment of the invention, the plate 155 for exhaust may reciprocate together with the showerhead 220 along the same direction which the showerhead 220 reciprocates along. The plate 155 for exhaust may be coupled to the same reciprocating mechanism of the showerhead 220. The plate 155 for exhaust may be coupled to a separate reciprocating mechanism.

According to an embodiment of the invention, the showerhead 220 of the ALD apparatuses 400 and 500 may comprise a hole for exhaust. The hole for exhaust may be disposed between the hole 121 for injecting the source precursor, the hole 123 for injecting the purge gas, the hole 125 for injecting the reactant precursor, and the hole 127 for injecting the purge gas. In this embodiment, a part of the source precursor, the purge gas and the reactant precursor may be exhausted through the hole for exhaust of the showerhead 220 and a part of them may be exhausted through the hole 156 for exhaust of the plate 155 for exhaust.

According to an embodiment of the invention, the plate 155 for exhaust of the ALD apparatuses 400 and 500 illustrated in FIGS. 14 and 16 may have the shape of the roller 55 like in the ALD apparatuses 100, 110 and 300 illustrated in FIG. 9, and therefore the showerhead 220 of the ALD apparatuses 400 and 500 may have a curved shape such that it surrounds the plate 155 for exhaust which has the shape of the roller 55.

According to an embodiment of the invention, unevenness (embossing) may be formed on a surface of the plate 155 for exhaust of the ALD apparatuses 400 and 500 illustrated in FIGS. 14 and 16 in order to decrease a contact area between the substrate 50 and the plate 155 for exhaust.

Although specific embodiments of the invention have been described and illustrated, the invention is not to be limited to the specific forms or arrangements of parts so described and illustrated. The scope of the invention is to be defined by the claims appended hereto and their equivalents.

The embodiments of the invention may be used to deposit the atomic layers on the substrates during manufacturing processes of OLED display and lightings, CIGS solar cell, Dye-sensitized solar cell, packaging for food and medical supplies, flexible glass substrate, lithium ion batteries and etc. The embodiments of the invention may be also used to deposit the atomic layers on barrier films to prevent permeation of moisture and oxygen.

What is claimed is:

1. An apparatus for depositing atomic layers comprising:
a moving mechanism configured to move a substrate along a first direction;
a showerhead comprising at least one injection unit wherein said injection unit comprises a hole for injecting first materials, a hole for injecting second materials which forms a reaction layer by a reaction with said first materials, and a hole for injecting purge gas towards said substrate; and
a moving mechanism configured to move said showerhead back and forth along a second direction between first and second locations,
wherein said showerhead is configured not to inject the second materials while said first materials is injected and not to inject the first materials while said second materials is injected.

2. The apparatus of claim 1 configured such that a point on said substrate is exposed to said first materials and said second materials alternately while said point on said substrate passes said showerhead by said moving mechanism of said substrate.

3. The apparatus of claim 1, said injection unit comprising at least one hole for exhaust wherein said first and second materials and said purge gas are exhausted through said at least one hole for exhaust.

4. The apparatus of claim 1 comprising a plate for exhaust disposed at an opposite side of said showerhead across said substrate wherein said plate for exhaust is configured to exhaust said first and second materials and said purge gas injected from said showerhead.

5. The apparatus of claim 4 wherein said substrate is permeable to gas.

6. The apparatus of claim 1 wherein said first and second directions are perpendicular to each other.

7. The apparatus of claim 1 wherein said first and second directions are the same.

8. The apparatus of claim 1 wherein a distance between said first and second locations is equal to a pitch of said at least one injection units.

9. The apparatus of claim 1 wherein a distance between said first and second locations is greater than a distance between said holes for injecting said first and second materials.

10. The apparatus of claim 1 wherein the number of said atomic layers deposited on said substrate is controlled by controlling a moving speed of said substrate along said first direction.

11. The apparatus of claim 1 wherein the number of said atomic layers deposited on said substrate is controlled by controlling a moving speed of said showerhead along said second direction.

12. The apparatus of claim 1 further comprising a second showerhead disposed at least one of before and after said showerhead wherein said second showerhead comprises a hole for injecting said first materials.

13. The apparatus of claim 1 comprising a roller configured to support said substrate wherein said showerhead is disposed adjacent to said roller and an injection surface of said showerhead is curved along a circumferential direction of said roller.

14. The apparatus of claim 13 wherein said second direction is said circumferential direction of said roller and said showerhead pivots back and forth along said circumferential direction.

15. The apparatus of claim 13 wherein said second direction is parallel to a rotational axis of said roller and said showerhead moves back and forth along a direction parallel to said rotational axis.
